(19) United States
(12) Patent Application Publication
(10) Pub. No.: US 2020/0389747 A1
(43) Pub. Date: Dec. 10, 2020

(54) METHOD FOR MANUFACTURING POLYCRYSTALLINE SILICON THIN FILM, POLYCRYSTALLINE SILICON THIN FILM, AND ACOUSTIC SENSOR

(71) Applicant: AAC Technologies Pte. Ltd., Singapore city (SG)

(72) Inventors: Kianheng Goh, Singapore (SG); Xiaohui Zhong, Shenzhen (CN); Wooicheang Goh, Singapore (SG); Kahkeen Lai, Singapore (SG)

(21) Appl. No.: 16/562,461

(22) Filed: Sep. 6, 2019

(30) Foreign Application Priority Data
Jun. 5, 2019 (CN) 201910487384.7

(51) Int. Cl. H04R 31/00; H01L 21/02; H04R 7/04; C23C 16/24; C23C 16/56

(52) U.S. Cl. CPC H04R 31/003; H01L 21/02595; H01L 21/02532; H01L 21/02576; H01L 21/02579; H04R 2307/025; H01L 21/02669; H04R 7/04; C23C 16/24; C23C 16/56; H01L 21/0262

(57) ABSTRACT

The present disclosure provides a method for manufacturing a polycrystalline silicon thin film, a polycrystalline silicon thin film and an acoustic sensor. The method includes: providing a base material, the base material including a baseplate and a polycrystalline silicon base film stacked with the baseplate; ex-situ doping one of boron, phosphorus and arsenic in the polycrystalline silicon base film to obtain a semi-finished product of the polycrystalline silicon thin film; thermally activating, and then annealing the semi-finished product to obtain the polycrystalline silicon thin film. The polycrystalline silicon thin film manufactured by the method according to the present disclosure has a high uniformity of grain growth, and a reduced surface roughness. Moreover, the polycrystalline silicon thin film also has an excellent mechanical strength, and thus is suitable for applications requiring high mechanical strength. Further, a passing rate in an air blowing test is relatively high.

### TECHNICAL FIELD

The present disclosure relates to the field of polycrystalline silicon thin film manufacture, and particularly, to a method for manufacturing a polycrystalline silicon thin film, a polycrystalline silicon thin film, and an acoustic sensor.

### BACKGROUND

At present, polycrystalline silicon thin films are usually manufactured by chemical vapor deposition (CVD). Specifically, a silicon substrate is placed into a reaction furnace, and silane gas is introduced into a reaction furnace under a certain temperature and a certain pressure to obtain silicon atoms by decomposition. The silicon atoms are deposited, crystallized, and then annealed, to form a polycrystalline silicon thin film. In order to ensure a certain mechanical strength of the polycrystalline silicon thin film, the polycrystalline silicon thin film is usually doped with an impurity element by in-situ doping. However, the polycrystalline silicon thin film manufactured through the above method has the following drawbacks:

1. The polycrystalline silicon thin film prepared by the existing method has a relatively high surface roughness after being annealed in a furnace, and thus cannot meet application requirements.

2. The polycrystalline silicon thin film obtained by the existing method has a poor mechanical strength, which are unsuitable for some applications with high requirements on the mechanical strength.

3. The polycrystalline silicon thin film obtained by the existing method has a relatively low passing rate in an air blowing test, i.e., having a low yield, thereby resulting in high cost of manufacturing.

Therefore, it is urgent to provide a new method for manufacturing the polycrystalline silicon thin film, in order to solve the above problems.

### BRIEF DESCRIPTION OF DRAWINGS

Many aspects of the exemplary embodiment can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a flow chart of a method for manufacturing a polycrystalline silicon thin film according to an embodiment of the present disclosure;

FIG. 2 is a structural schematic diagram of a method for manufacturing a polycrystalline silicon thin film according to an embodiment of the present disclosure;

FIG. 3 is a flow chart of a method for manufacturing a base material provided by an embodiment of the present disclosure; and

FIG. 4 is schematic diagram illustrating passing rates in the air blowing tests of a polycrystalline silicon thin film obtained by an existing manufacturing method and a polycrystalline silicon thin film obtained by the manufacturing method according to the present embodiment.

### DESCRIPTION OF EMBODIMENTS

The present disclosure will be further described with reference to the accompanying drawings and the embodiments.

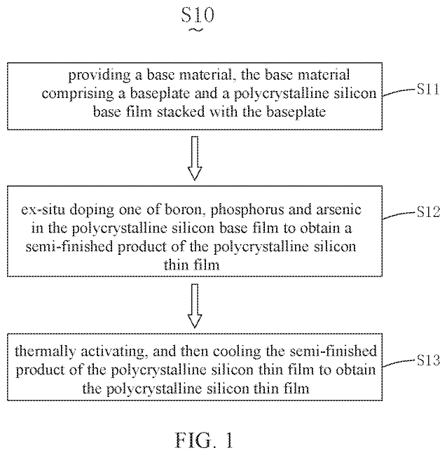

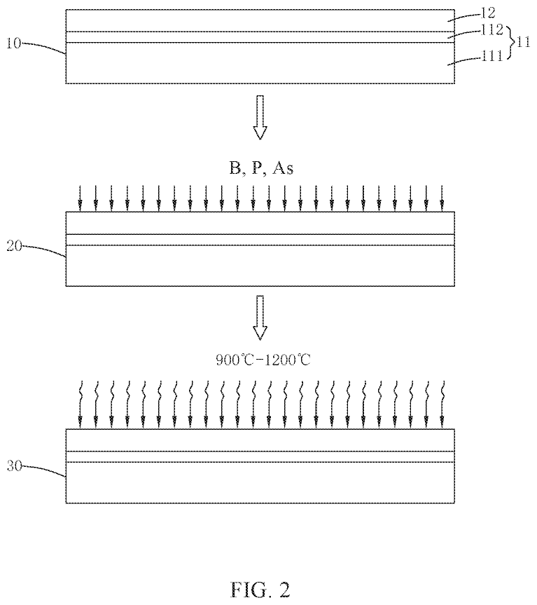

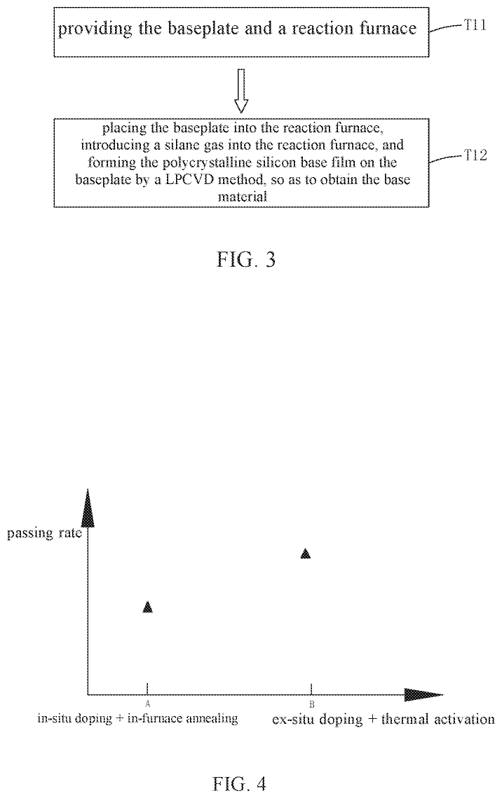

Referring to FIG. 1-3, an embodiment of the present disclosure provides a method S10 for manufacturing a polycrystalline silicon thin film. The method S10 for manufacturing a polycrystalline silicon thin film includes following steps:

Step S11, providing a base material 10, the base material 10 including a baseplate 11 and a polycrystalline silicon base film 12 stacked with the baseplate 11;

Step S12, ex-situ doping one of boron, phosphorus and arsenic in the polycrystalline silicon base film 12, to obtain a semi-finished product 20 of the polycrystalline silicon thin film;

Step S13, thermally activating, and then cooling the semi-finished product 20 of the polycrystalline silicon thin film, to obtain the polycrystalline silicon thin film 30.

In the present embodiment, by ex-situ doping one of boron, phosphorus and arsenic in the polycrystalline silicon base film 12 to obtain the semi-finished product 20 of the polycrystalline silicon thin film, and by thermally activating, and then cooling the semi-finished product 20 of the polycrystalline silicon thin film to obtain the polycrystalline silicon thin film 30, the polycrystalline silicon thin film 30 manufactured by this method has good grain growth and uniformity, which effectively reduces a surface roughness of the polycrystalline silicon thin film 30. Moreover, the polycrystalline silicon thin film 30 manufactured by this method has an excellent mechanical strength, and thus is suitable for applications with high requirements on the mechanical strength. Further, it is also found in an air blowing test that the polycrystalline silicon thin film 30 obtained by this method has a relatively high passing rate in the air blowing test, such that the cost is effectively reduced for producing the same number of polycrystalline silicon thin films 30.

The base material 10 provided in the step S11 can be prepared by a low-pressure chemical vapor deposition (LPCVD) method, which specifically includes the following steps:

Step T11, providing the baseplate 11 and a reaction furnace;

Step T12, placing the baseplate 11 into the reaction furnace, introducing a silane gas into the reaction furnace, and forming the polycrystalline silicon base film 12 on the baseplate 11 by the LPCVD method, so as to obtain the base material 10.

In an embodiment, in the process of preparing the base material 10, the silane gas introduced can be SiH₄ (monosilane), Si₂H₆ (disilane), or a gas mixture of monosilane and disilane.

In an embodiment, in the process of preparing the base material 10, a temperature in the reaction furnace is 500° C. to 700° C.

In an embodiment, in the process of preparing the base material 10, a gas pressure in the reaction furnace is 200 mtorr to 350 mtorr.

In an embodiment, the baseplate 11 includes a silicon substrate 111 and a silicon dioxide film 112 stacked with the silicon substrate 111. The polycrystalline silicon base film 12 is formed on a side of the silicon dioxide film 112 facing away from the silicon substrate 111.

In the step S12, a specific process of doping one of boron, phosphorus and arsenic in the polycrystalline silicon base film 12 is as follow: after preparing the base material 10, introducing, but not limited to, one of borane (B₂H₆), phosphine (PH₃) and arsine (AsH₃) into the reaction furnace to ex-situ dope one of boron, phosphorus and arsenic in the polycrystalline silicon base film 12. In the specific doping process, taking the doping of phosphorus as an example, the PH₃ (phosphine) gas is introduced into the reaction furnace, and decomposes into phosphorus ions and hydrogen ions under the high temperature in the reaction furnace. The phosphorus ions subside and are embedded between silicon ions, and the hydrogen ions are polymerized into hydrogen gas to be discharged.

It should be noted that, before introducing one of borane (B₂H₆), phosphine (PH₃) and arsine (AsH₃) into the reaction furnace to ex-situ dope one of boron, phosphorus and arsenic in the polycrystalline silicon base film 12, no silane gas is remained in the reaction furnace. For example, after the base material 10 is prepared by introducing the silane gas in the reaction furnace, the silane gas in the reaction furnace can be completely discharged. Then, the silane gas containing one of borane (B₂H₆), phosphine (PH₃) and arsine (AsH₃) is introduced to dope one of boron, phosphorus and arsenic. During the above process, a content of borane, phosphine and arsine in the introduced silane gas can be adjusted according to actual needs. The complete discharge of the remaining silane gas in the reaction furnace after preparing the base material is to prevent the remaining silane gas in the non-doping process from affecting the content of borane, phosphine and arsine, thereby ensuring a stable content thereof and the doping effect.

In the step S13, the step of thermally activating the semi-finished product 20 of the polycrystalline silicon thin film specifically includes: placing the semi-finished product 20 of the polycrystalline silicon thin film into an atmosphere at a temperature of 900° C. to 1200° C. to be heated. During thermally activating the semi-finished product 20 of the polycrystalline silicon thin film, the semi-finished product 20 of the polycrystalline silicon thin film, which has been ex-situ doped with boron, phosphorus or arsenic, may partially be recrystallized to form the polycrystalline silicon thin film 30 having a low surface roughness and an excellent mechanical strength. The different requirements on the mechanical strength of the polycrystalline silicon thin films 30 can be met by adjusting a duration and temperature of the thermal activation. It should be noted that, since the semi-finished product 20 of the polycrystalline silicon thin film is ex-situ doped with one of boron, phosphorus and arsenic, the duration of the thermal activation can be greatly shortened, which avoids a formation of excessively large grains during recrystallization, thereby reducing the surface roughness of the polycrystalline silicon thin film 30.

An embodiment of the present disclosure also provides a polycrystalline silicon thin film 30, and the polycrystalline silicon thin film is manufactured by the above method S10 for manufacturing a polycrystalline silicon thin film. The polycrystalline silicon thin film 30, as being manufactured by the above method S10 for manufacturing a polycrystalline silicon thin film, has good grain growth and uniformity, and in the meantime, the polycrystalline silicon thin film 30 also has a reduced surface roughness and improved mechanical strength, and a pass rate in the air blowing test is increased. The polycrystalline silicon thin film 30 can be applied in various fields such as solar cells, transistors, sound conversion propagation, and the like.

An embodiment of the present disclosure also provides an acoustic sensor, and the acoustic sensor includes the polycrystalline silicon thin film 30 described above.

FIG. 4 is schematic diagram illustrating passing rates in the air blowing tests of a polycrystalline silicon thin film obtained by an existing manufacturing method and a polycrystalline silicon thin film obtained by the manufacturing method according to the present embodiment. In FIG. 4, Point A in the abscissa represents the existing manufacturing method (adopting in-situ doping and in-furnace annealing), and Point B in the abscissa fabricating the manufacturing method according to the present embodiment (adopting ex-situ doping and thermal activation). B coordinate indicates the passing rate of the polycrystalline silicon thin film in the air blowing test. It can be seem from FIG. 4 that the passing rate in the air blowing test of the polycrystalline silicon thin film obtained by the manufacturing method according to the present embodiment is significantly improved when compared with the passing rate in the air blowing test of the polycrystalline silicon thin film obtained by the existing manufacturing method.

The above is only the embodiment of the present disclosure, and it should be noted that those skilled in the art can make improvements without departing from the inventive concept of the present disclosure, but these are all fall into the protection scope of the present disclosure.

What is claimed is:

1. A method for manufacturing a polycrystalline silicon thin film, comprising steps of:
providing a base material, the base material comprising a baseplate and a polycrystalline silicon base film stacked with the baseplate;
ex-situ doping one of boron, phosphorus and arsenic in the polycrystalline silicon base film to obtain a semi-finished product of the polycrystalline silicon thin film; and
thermally activating, and then cooling the semi-finished product of the polycrystalline silicon thin film to obtain the polycrystalline silicon thin film.

2. The method for manufacturing a polycrystalline silicon thin film as described in claim 1, wherein the base material is provided through steps of:
providing the baseplate and a reaction furnace; and
placing the baseplate into the reaction furnace, introducing a silane gas into the reaction furnace, and forming the polycrystalline silicon base film on the baseplate by a LPCVD method, so as to obtain the base material.

3. The method for manufacturing a polycrystalline silicon thin film as described in claim 2, wherein in the step of the thermally activating the semi-finished product of the polycrystalline silicon thin film, a temperature in the reaction furnace is 900° C. to 1200° C.

4. The method for manufacturing a polycrystalline silicon thin film as described in claim 3, wherein the baseplate comprises a silicon substrate and a silicon dioxide film stacked with the silicon substrate, and the polycrystalline silicon base film is formed on a side of the silicon dioxide film facing away from the silicon substrate.

5. The method for manufacturing a polycrystalline silicon thin film as described in claim 3, wherein during providing the base material, the temperature in the reaction furnace is 500° C. to 700° C.

6. The method for manufacturing a polycrystalline silicon thin film as described in claim 3, wherein during providing the base material, a gas pressure in the reaction furnace is 200 mtorr to 350 mtorr.

7. The method for manufacturing a polycrystalline silicon thin film as described in claim 2, wherein after providing the base material, one of borane, phosphine and arsine is introduced into the reaction furnace to ex-situ dope one of boron, phosphorus and arsenic in the polycrystalline silicon base film.

8. A polycrystalline silicon thin film, manufactured by the method for manufacturing a polycrystalline silicon thin film as described in any one of claim 1.

9. An acoustic sensor, comprising the polycrystalline silicon thin film as described in claim 8.
